(19) United States
(12) Patent Application Publication
(10) Pub. No.: US 2026/0162732 A1
(43) Pub. Date: Jun. 11, 2026

(54) MEMORY DEVICE AND METHOD FOR OPERATING THE SAME

(71) Applicant: SK hynix Inc., Gyeonggi-do (KR)

(72) Inventor: Seong Uk KIM, Gyeonggi-do (KR)

(21) Appl. No.: 19/412,859

(22) Filed: Dec. 9, 2025

(30) Foreign Application Priority Data
Dec. 11, 2024 (KR) 10-2024-0183291

(51) Int. Cl. G11C 16/26; G11C 16/08; G11C 16/24

(52) U.S. Cl. CPC G11C 16/26; G11C 16/08; G11C 16/24

(57) ABSTRACT

A memory device for storing data therein and a method for operating the same are disclosed. The memory device includes a memory cell array including a first page and a second page, each of which includes a plurality of memory cells; a page buffer configured to detect data stored in a selected page among the first page and the second page and store the detected data therein; a cache buffer configured to receive data stored in the page buffer and store the received data, and a control circuit configured to perform a cache update operation for the first page and a cell read operation for the second page, wherein at least a part of the cache update operation for the first page overlaps the cell read operation for the second page.

### CROSS-REFERENCE TO RELATED APPLICATION

This patent document claims the priority and benefits of Korean patent application No. 10-2024-0183291, filed on December 11, 2024, the disclosure of which is incorporated herein by reference in its entirety.

### TECHNICAL FIELD

The technology and implementations disclosed in this patent document generally relate to a memory device for storing data therein and a method for operating the same.

### BACKGROUND

A semiconductor memory device may include a plurality of memory cells for storing data therein. In addition, the semiconductor memory device may be classified into a nonvolatile memory device that can maintain stored data even when power supply is interrupted, and a volatile memory device that does not preserve data when power supply is interrupted.

A nonvolatile memory device may perform a read operation for reading data stored in a memory cell, a program operation for writing data in a memory cell, and an erase operation for initializing a memory cell.

### SUMMARY

Various embodiments of the present disclosure relate to a memory device capable of efficiently performing a read operation and a method for operating the same.

In accordance with an embodiment of the present disclosure, a memory device may include: a memory cell array including a first page and a second page, each of which includes a plurality of memory cells; a page buffer configured to detect data stored in a selected page among the first page and the second page and store the detected data therein; a cache buffer configured to receive data stored in the page buffer and store the received data; and a control circuit configured to perform a cache update operation for the first page and a cell read operation for the second page, wherein at least a part of the cache update operation for the first page overlaps the cell read operation for the second page.

In accordance with another embodiment of the present disclosure, a memory device may include: a memory cell array including a first page and a second page, each of which includes a plurality of memory cells; a page buffer configured to detect data stored in a selected page among the first page and the second page and store the detected data therein; a cache buffer configured to receive data stored in the page buffer and store the received data; and a control circuit configured to perform an operation of precharging at least one bit line connected to the second page when the cache buffer receives data of the first page stored in the page buffer.

In accordance with another embodiment of the present disclosure, a method for operating a memory device may include: detecting data stored in a first page of a memory cell array and storing the detected data in a page buffer; moving data of the first page stored in the page buffer to a cache buffer and storing the data in the cache buffer; and detecting data stored in a second page of the memory cell array and storing the detected data in the page buffer, wherein the moving data of the first page to the cache buffer and storing the data in the cache buffer and the detecting data of the second page and storing the detected data in the page buffer are performed in an overlapping manner.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an example of a memory system according to an embodiment of the present disclosure.

FIG. 2 is a block diagram illustrating an example of a memory device shown in FIG. 1 according to an embodiment of the present disclosure.

FIG. 3 is a schematic diagram illustrating an example of a plane selector shown in FIG. 2 according to an embodiment of the present disclosure.

FIG. 4 is a schematic diagram illustrating example operations related to a plane included in a memory cell array shown in FIG. 2 according to an embodiment of the present disclosure.

FIG. 5 is a timing diagram illustrating example operations of the memory system shown in FIG. 1 according to an embodiment of the present disclosure.

FIGS. 6A to 6E are schematic diagrams briefly illustrating example operations of the memory system in each time section shown in FIG. 5 according to an embodiment of the present disclosure.

### DETAILED DESCRIPTION

Embodiments of the present disclosure provide examples of a semiconductor memory device for storing data therein and a method for operating the same, that may be used in configurations to substantially address one or more technical or engineering issues and to mitigate limitations or disadvantages encountered in some other semiconductor memory devices. Some implementations of the present disclosure relate to a semiconductor memory device capable of efficiently performing a read operation and a method for operating the same. In recognition of the issues above, the present disclosure may provide the semiconductor memory device in which a cache update operation for a specific page and a cell read operation for a subsequent page are performed in an overlapping manner, thereby reducing a time required for the read operation.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

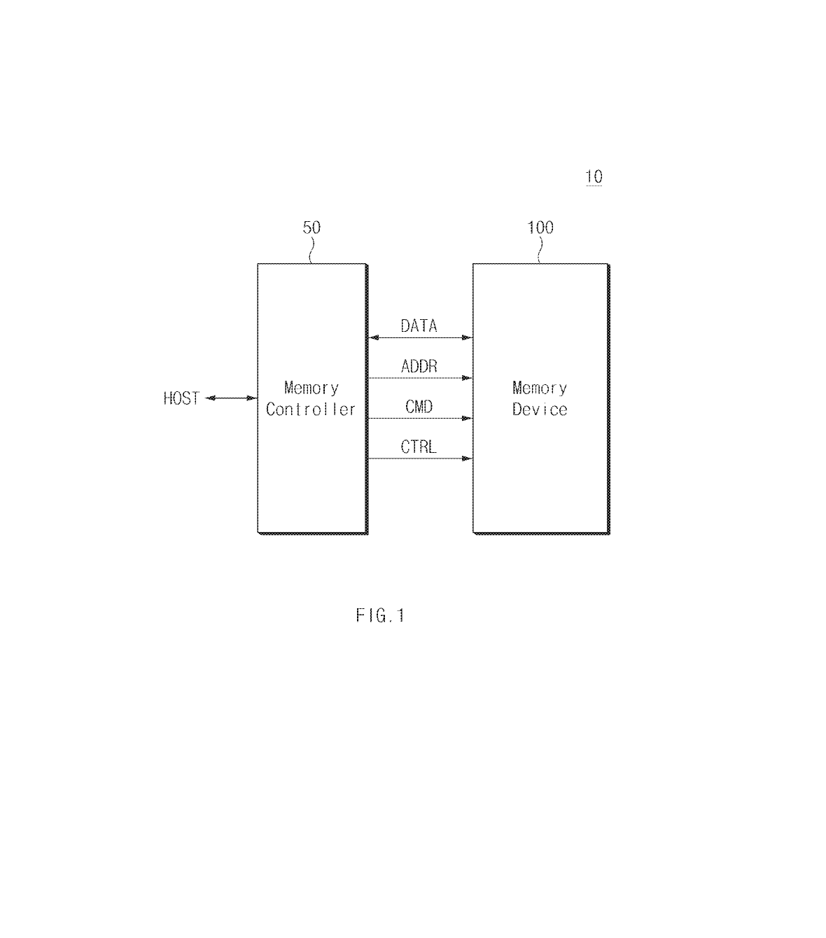

FIG. 1 is a block diagram illustrating an example of a memory system 10 according to embodiments of the present disclosure.

Referring to FIG. 1, the memory system 10 may include a memory device 100 and a memory controller 50.

The memory system 10 may be implemented as an internal memory embedded in an electronic system (e.g., a smartphone, a tablet, a computer, a TV, etc.). For example, the memory system 10 may be an embedded universal flash storage (UFS), an embedded multimedia card (eMMC), or a solid state drive (SSD). According to one embodiment, the memory system 10 may be implemented as an external memory detachably coupled to an electronic device, and may be, for example, a UFS memory card, a compact flash (CF) card, a secure digital (SD) card, a micro-Secure Digital (micro-SD) card, a mini-Secure Digital (mini-SD) card, an eXtreme Digital (xD) card, or a memory stick.

The memory system 10 may store data received from a host in the memory device 100 based on an access request from the host, or may read data requested by the host from the memory device 100 and transmit the read data to the host.

The memory device 100 serving as a semiconductor memory device may include a plurality of memory cells, each of which stores data. According to one embodiment, each of the plurality of memory cells may be a nonvolatile memory cell that maintains stored data when power supply is interrupted. For example, when the memory cell is a nonvolatile memory cell, the memory device 100 may be implemented as an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like. Hereinafter, embodiments of the present disclosure will be described with regard to an example in which the plurality of memory cells is NAND flash memory cells, but the technical idea of the present disclosure is not limited thereto. The memory device 100 may perform program, read, and/or erase operations under control of the memory controller 50.

The memory controller 50 may provide a control signal (CTRL), a command (CMD), and an address (ADDR) to the memory device 100. The control signal (CTRL) may include information necessary for the memory device 100 to perform an operation corresponding to the command (CMD) received from the memory controller 50. For example, the control signal (CTRL) may include information about the sensing parameters necessary for the memory device 100 to read data from memory cells. The command (CMD) may indicate an operation to be performed by the memory device 100 during the program, read, or erase operation. The address (ADDR) may indicate a position at which the memory controller 50 desires to access data in the memory device 100. Data (DATA) may be transmitted and/or received between the memory controller 50 and the memory device 100 based on the command (CMD) and the address (ADDR).

The memory controller 50 may control various operations of the memory device 100 in response to an access request from the host, for example, the program operation for programming data (DATA) in the memory device 100, the read operation for reading data (DATA) from the memory device 100, and/or the erase operation for erasing data (DATA) of the memory device 100. For example, the memory controller 50 may transmit data (DATA) received from the host to the memory device 100 by executing a write command, or may transmit data (DATA) read from the memory device 100 to the host by executing a read command. In addition, the memory controller 50 may provide a clock signal, a chip selection signal, etc. to the memory device 100.

In the present disclosure, the read operation may include a program verification operation that verifies programmed data during a program operation and an erase verification operation that verifies erased data during an erase operation, but the scope of the present disclosure is not limited thereto.

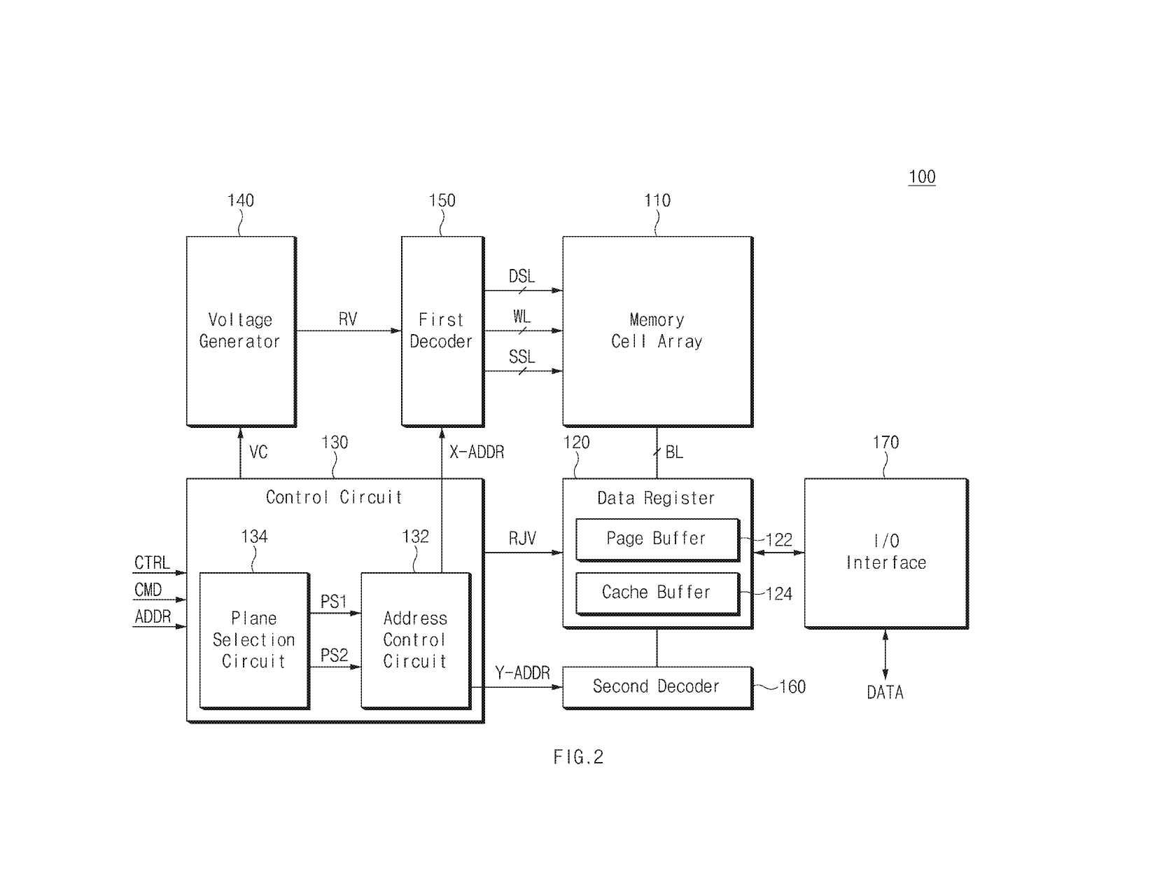

FIG. 2 is a block diagram illustrating an example of a memory device 100 shown in FIG. 1 based on some embodiments of the present disclosure.

Referring to FIG. 2, the memory device 100 may include a memory cell array 110, a data register 120, a control circuit 130, a voltage generator 140, a first decoder 150, a second decoder 160, and an input and output (input/output) (I/O) interface 170.

The memory cell array 110 may include a plurality of memory cells. The memory cell array 110 may be connected to drain selection lines (DSLs), word lines (WLs), source selection lines (SSLs), and bit lines (BLs). The memory cell array 110 may be connected to the first decoder 150 through the drain selection lines (DSLs), the word lines (WLs), and the source selection lines (SSLs), and may be connected to the data register 120 through the bit lines (BLs).

The memory cell array 110 may include a plurality of planes, each of which includes a plurality of memory blocks. Each memory block may include a plurality of memory cells arranged in a two-dimensional (2D) structure or a three-dimensional (3D) structure. The memory cell array 110 may include at least one of a single-level cell (SLC) block including single-level cells (SLCs), a multi-level cell (MLC) block including multi-level cells (MLCs), a triple-level cell (TLC) block including triple-level cells (TLCs), and a quad-level cell (QLC) block including quad-level cells (QLCs). For example, some of the plurality of memory blocks may be single-level cell (SLC) blocks, and other memory blocks may include multi-level cell (MLC) blocks, triple-level cell (TLC) blocks, or quad-level cell (QLC) blocks.

The data register 120 may operate in response to a control signal from the second decoder 160. The data register 120 may temporarily store data (DATA) received from the input / output (I/O) interface 170 and then transmit the data (DATA) to the memory cell array 110. In addition, the data register 120 may temporarily store data (DATA) received from the memory cell array 110 and then transmit the data (DATA) to the I/O interface 170.

The data register 120 may include a page buffer 122 and a cache buffer 124. Although FIG. 2 illustrates one data register 120 including one page buffer 122 and one cache buffer 124, a plurality of data registers 120 can be connected to the bit lines (BL). Here, the plurality of page buffers 122 and the plurality of cache buffers 124 may be connected in one-to-one correspondence with each other. In addition, the page buffer and the cache buffer connected in one-to-one correspondence with each other may correspond to each plane included in the memory cell array 110. That is, one plane, one page buffer, and one cache buffer may correspond to each other.

The page buffer 122 may be connected to the bit lines (BLs) and may operate under the control of the second decoder 160. For example, the page buffer 122 may operate as a write driver or a sense amplifier.

According to one embodiment, during the program operation, the page buffer 122 may operate as a write driver to apply a voltage according to data (DATA) to be stored in the memory cell array 110 to the bit lines (BLs).

According to one embodiment, during the read operation, the page buffer 122 may operate as a sense amplifier, and may detect data (DATA) stored in the memory cell array 110 through the bit lines (BLs). The page buffer 122 may detect data (DATA) using a read judgment voltage (RJV) received from the control circuit 130. For example, the page buffer 122 may determine data (DATA) by comparing a voltage level of a signal received through the bit lines (BLs) with the read judgment voltage (RJV). In addition, the page buffer 122 may store the determined data (DATA).

The cache buffer 124 may be connected to the page buffer 122 and may operate under the control of the second decoder 160.

According to one embodiment, during the program operation, the cache buffer 124 may receive data (DATA) to be stored in the memory cell array 110 from the I/O interface 170, may temporarily store the data (DATA), and may transmit the data (DATA) to the page buffer 122.

According to one embodiment, during the read operation, the cache buffer 124 may receive data (DATA) that has been determined and stored by the page buffer 122, may temporarily store the data (DATA), and may transmit the data (DATA) to the I/O interface 170.

The control circuit 130 may output internal control signals for programming (writing) data (DATA) in the memory cell array 110 or reading data (DATA) from the memory cell array 110 based on the command (CMD), the address (ADDR), and the control signal (CTRL).

According to one embodiment, the control circuit 130 may set a read condition for normally reading data (DATA) stored in the memory cell array 110. The read condition may include various conditions for a read judgment voltage (RJV), a read voltage to be applied to selected memory cells, a pass voltage to be applied to unselected memory cells, a drain selection line voltage to be applied to the drain selection line (DSL), and/or a source selection line voltage to be applied to the source selection line (SSL).

The control circuit 130 may output a voltage control signal (VC) for controlling the levels of various reference voltages generated by the voltage generator 140 so that the voltage generator 140 can generate a reference voltage (RV) determined according to the read condition. In addition, the control circuit 130 may generate a read judgment voltage (RJV) determined according to the read condition, and may transmit the read judgment voltage (RJV) to the data register 120.

The control circuit 130 may include an address control circuit 132 and a plane selection circuit 134.

The address control circuit 132 may provide a row address (X-ADDR) for selecting the word line (WL) to the first decoder 150. According to one embodiment, the address control circuit 132 may generate a row address (X-ADDR) based on a first plane selection signal (PS1) and an address (ADDR) indicating the position of a memory cell to be accessed by the memory controller 50. The first plane selection signal (PS1) may be a signal for selecting a word line corresponding to one of a plurality of planes of the memory cell array 110. For example, the address control circuit 132 may output a row address (X-ADDR) corresponding to a plane selected by the first plane selection signal (PS1) among the addresses (ADDR) indicating the position of a memory cell to be accessed by the memory controller 50.

The address control circuit 132 may provide a column address (Y-ADDR) for selecting the data register 120 to the second decoder 160. According to one embodiment, the address control circuit 132 may generate a column address (Y-ADDR) based on a second plane selection signal (PS2) and an address (ADDR) indicating the position of a memory cell to be accessed by the memory controller 50. The second plane selection signal (PS2) may be a signal for selecting a data register corresponding to one of the plurality of planes of the memory cell array 110. For example, the address control circuit 132 may output a column address (Y-ADDR) corresponding to a plane selected by the second plane selection signal (PS2) among the addresses (ADDR) indicating the position of a memory cell to be accessed by the memory controller 50.

The plane selection circuit 134 may independently select word lines corresponding to a selected plane among the plurality of planes included in the memory cell array 110 and a data register corresponding to the selected plane among the plurality of planes. The plane selection circuit 134 may generate a first plane selection signal (PS1) for selecting a word line corresponding to one of the plurality of planes of the memory cell array 110 and a second plane selection signal (PS2) for selecting a data register corresponding to one of the plurality of planes of the memory cell array 110. That is, the plane selection circuit 134 may select word lines and data registers of different planes at the same time point by generating each of the first plane selection signal (PS1) and the second plane selection signal (PS2).

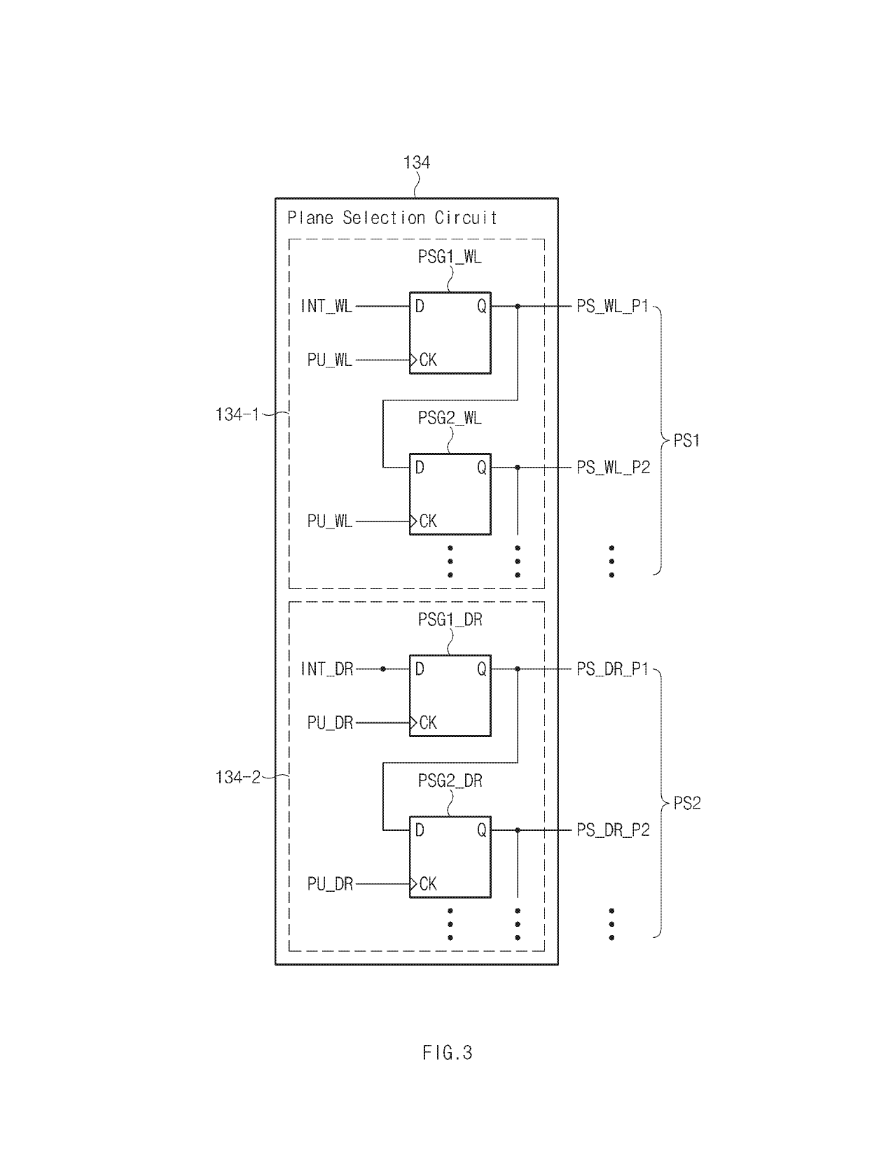

A more detailed description of the plane selection circuit 134 will be described later with reference to FIG. 3.

Although FIG. 2 illustrates the control circuit 130 designed to include a plane selection circuit 134 for convenience, other implementations are also possible. For example, the plane selection circuit 134 may be located outside the control circuit 130.

The voltage generator 140 may generate various types of reference voltages (RV) required to perform a program operation, a read operation, and an erase operation on the memory cell array 110 based on a voltage control signal (VC). Specifically, the voltage generator 140 may generate a word line voltage (e.g., a program voltage, a read voltage, a pass voltage, an erase verification voltage, or a program verification voltage) to be applied to a word line (WL). Further, the voltage generator 140 may generate a drain selection line voltage to be applied to a drain selection line (DSL) and a source selection line voltage to be applied to a source selection line (SSL). That is, the reference voltages (RVs) may include a word line voltage, a drain selection line voltage, and a source selection line voltage.

The first decoder 150 may select one of a plurality of planes in response to a row address (X-ADDR), and may select one of the word lines (WL) of the selected memory block. The first decoder 150 may supply voltages required for a program operation, a read operation, or an erase operation for a memory cell connected to the selected word line (WL) to the word line (WL), the drain selection line (DSL), and the source selection line (SSL) using the reference voltages (RVs).

The second decoder 160 may select a data register 120 corresponding to a selected plane among a plurality of planes in response to a column address (Y-ADDR). The second decoder 160 may supply a voltage required for the operation of the selected data register 120.

The I/O interface 170 may perform transmission and reception (i.e., communication) of data (DATA) between the data register 120 and the memory controller 50. Although FIG. 2 illustrates that the control circuit 130 directly receives the command (CMD), the address (ADDR), and the control signal (CTRL) from the memory controller 50, other implementations are also possible. According to another embodiment, the command (CMD), the address (ADDR), and the control signal (CTRL) may be received by the control circuit 130 through the I/O interface 170.

According to one embodiment, the I/O interface 170 may perform signal processing (e.g., noise cancellation, amplification, etc.) on transmission/reception (Tx/Rx) signals and data.

FIG. 3 is a schematic diagram illustrating an example of the plane selection circuit 134 shown in FIG. 2 according to embodiments of the present disclosure.

Referring to FIG. 3, the plane selection circuit 134 may include a first plane selector 134-1 and a second plane selector 134-2.

The first plane selector 134-1 may include a plurality of word-line plane selection signal generators (PSG1_WL to PSGn_WL) for generating a first plane selection signal (PS1). Here, ‘n’ may correspond to the number of planes included in the memory cell array 110. Although not shown in FIG. 3, the word-line plane selection signal generator (PSGn_WL) may denote the last word-line plane selection signal generator included in the first plane selector 134-1.

That is, the plurality of word-line plane selection signal generators (PSG1_WL to PSGn_WL) may correspond to the plurality of planes included in the memory cell array 110, respectively, so that the word-line plane selection signal generators (PSG1_WL to PSGn_WL) may generate word-line plane selection signals (PS_WL_P1 to PS_WL_Pn) indicating activation or deactivation (or selection or non-selection) of word lines respectively corresponding to the planes included in the memory cell array 110. The word-line plane selection signals (PS_WL_P1 to PS_WL_Pn) may be included in the first plane selection signal (PS1). The word-line plane selection signal corresponding to the selected plane among the word-line plane selection signals (PS_WL_P1 to PS_WL_Pn) may have a logic high level, and the remaining word-line plane selection signals may have a logic low level.

In FIG. 3, for convenience, the operation of the first plane selector 134-1 will be described centering upon the first word-line plane selection signal generator (PSG1_WL) corresponding to the first plane of the memory cell array 110 and the second word-line plane selection signal generator (PSG2_WL) corresponding to the second plane of the memory cell array 110. Each of the plurality of word-line plane selection signal generators (PSG1_WL to PSGn_WL) will hereinafter be described assuming that each word-line plane selection signal generator serves as a D flip-flop, but the scope of the present disclosure is not limited thereto, and the function of the first plane selector 134-1 to be described below can also be implemented through other elements (e.g., JK flip-flop).

The first word-line plane selection signal generator (PSG1_WL) may include a clock terminal (CK), an input terminal (D), and an output terminal (Q). In response to an edge (e.g., a rising edge) of the first plane update signal (PU_WL) applied to the clock terminal (CK), the first word-line plane selection signal generator (PSG1_WL) may output a first initialization signal (INT_WL) applied to the input terminal (D) as a first word-line plane selection signal (PS_WL_P1) through the output terminal (Q). The first plane update signal (PU_WL) may select a word line corresponding to a selected plane among the plurality of planes.

The second word-line plane selection signal generator (PSG2_WL) may include a clock terminal (CK), an input terminal (D), and an output terminal (Q). In response to an edge (e.g., a rising edge) of the first plane update signal (PU_WL) applied to the clock terminal (CK), the second word-line plane selection signal generator (PSG2_WL) may output a first word-line plane selection signal (PS_WL_P1) applied to the input terminal (D) as the second word-line plane selection signal (PS_WL_P2) through the output terminal (Q).

Accordingly, the first plane selector 134-1 may output the initial voltage level of the first initialization signal (INT_WL) as the first word-line plane selection signal (PS_WL_P1) in response to a first edge (e.g., a first rising edge) of the first plane update signal (PU_WL), and may output the initial voltage level of the first initialization signal (INT_WL) as the second word-line plane selection signal (PS_WL_P2) in response to a second edge (e.g., a second rising edge) of the first plane update signal (PU_WL). As described above, the first plane selector 134-1 may sequentially output the first to N-th word-line plane selection signals (PS_WL_P1 to PS_WL_Pn) in response to the edge of the first plane update signal (PU_WL) that sequentially generates the initial voltage level of the first initialization signal (INT_WL).

In this case, the initial voltage level of the first initialization signal (INT_WL) may be a voltage level (for example, measured) before the first edge of the first plane update signal (PU_WL) occurs. For example, the initial voltage level of the first initialization signal (INT_WL) may be a logic high level. The first initialization signal (INT_WL) may maintain the initial voltage level and then change to a voltage level (e.g., a logic low level) less than the initial voltage level immediately after the first edge of the first plane update signal (PU_WL) occurs.

The second plane selector 134-2 may include a plurality of data register plane selection signal generators (PSG1_DR to PSGn_DR), each of which generates a second plane selection signal (PS2). Here, ‘n’ may correspond to the number of planes included in the memory cell array 110. Although not shown in FIG. 3, the data register plane selection signal generator (PSGn_DR) may mean the last word-line plane selection signal generator included in the second plane selector 134-2.

That is, the plurality of data register plane selection signal generators (PSG1_DR to PSGn_DR) may respectively correspond to the planes included in the memory cell array 110, so that the data register plane selection signal generators (PSG1_DR to PSGn_DR) may generate data register plane selection signals (PS_DR_P1 to PS_DR_Pn) indicating activation or deactivation (or selection or non-selection) of the data registers respectively corresponding to the planes included in the memory cell array 110. Among the data register plane selection signals (PS_DR_P1 to PS_DR_Pn), a data register plane selection signal corresponding to the selected plane may have a logic high level, and the remaining data register plane selection signals may have a logic low level.

In FIG. 3, for convenience, the operation of the second plane selector 134-2 will be described centering upon the first data register plane selection signal generator (PSG1_DR) corresponding to the first plane of the memory cell array 110 and the second data register plane selection signal generator (PSG2_DR) corresponding to the second plane of the memory cell array 110. In addition, although each of the plurality of data register plane selection signal generators (PSG1_DR to PSGn_DR) is described assuming that each data register plane selection signal generator (PSG1_DR to PSGn_DR) is a D flip-flop, other implementations are also possible, and the function of the second plane selector 134-2 to be described below may be implemented through other elements (e.g., a JK flip-flop).

The first data register plane selection signal generator (PSG1_DR) may include a clock terminal (CK), an input terminal (D), and an output terminal (Q). In response to an edge (e.g., a rising edge) of the second plane update signal (PU_DR) applied to the clock terminal (CK), the first data register plane selection signal generator (PSG1_DR) may output a second initialization signal (INT_DR) applied to the input terminal (D) as the first data register plane selection signal (PS_DR_P1) through the output terminal (Q). The second plane update signal (PU_DR) may be a signal for selecting a data register corresponding to the selected plane among the plurality of planes.

The second data register plane selection signal generator (PSG2_DR) may include a clock terminal (CK), an input terminal (D), and an output terminal (Q). In response to an edge (e.g., a rising edge) of the second plane update signal (PU_DR) applied to the clock terminal (CK), the second data register plane selection signal generator (PSG2_DR) may output the first data register plane selection signal (PS_DR_P1) applied to the input terminal (D) as the second data register plane selection signal (PS_DR_P2) through the output terminal (Q).

Accordingly, the second plane selector 134-2 may output the initial voltage level of the second initialization signal (INT_DR) as the first data register plane selection signal (PS_DR_P1) in response to the first edge (e.g., the first rising edge) of the second plane update signal (PU_DR), and may output the initial voltage level of the second initialization signal (INT_DR) as the second data register plane selection signal (PS_DR_P2) in response to the second edge (e.g., the second rising edge) of the second plane update signal (PU_DR). As described above, the second plane selector 134-2 may sequentially output the first to N-th data register plane selection signals (PS_DR_P1 to PS_DR_Pn) in response to the edge of the second plane update signal (PU_DR) that sequentially generates the initial voltage level of the second initialization signal (INT_DR).

In this case, the initial voltage level of the second initialization signal (INT_DR) may be a voltage level before the first edge of the second plane update signal (PU_DR) occurs. For example, the initial voltage level of the second initialization signal (INT_DR) may be a logic high level. The second initialization signal (INT_DR) may maintain the initial voltage level and then change to a voltage level (e.g., a logic low level) less than the initial voltage level immediately after the first edge of the second plane update signal (PU_DR) occurs.

The first plane selector 134-1 generates the first plane selection signal (PS1) and the second plane selector 134-2 generates the second plane selection signal (PS2), so that selection of a word line corresponding to one of the plurality of planes and selection of a data register corresponding to one of the plurality of planes can be performed independently.

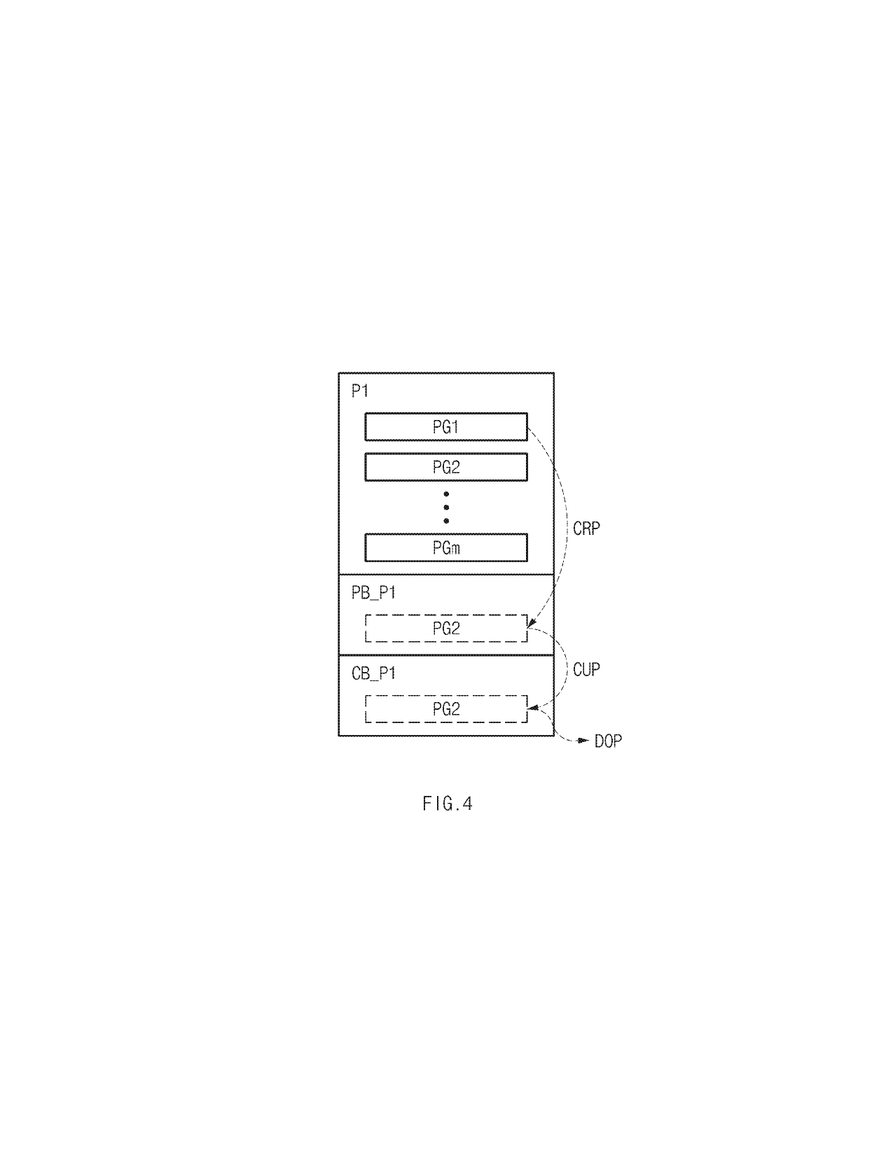

FIG. 4 is a schematic diagram illustrating example operations related to a plane included in the memory cell array 110 shown in FIG. 2 according to embodiments of the present disclosure.

Referring to FIG. 4, a first plane (P1) included in the memory cell array 110 (for example, as shown in FIG. 2), a first page buffer (PB_P1) corresponding to the first plane (P1), and a first cache buffer (CB_P1) corresponding to the first plane (P1) are illustrated. The first page buffer (PB_P1) and the first cache buffer (CB_P1) may also correspond to each other. Although FIG. 4 illustrates the first plane (P1) as an example, other implementations are also possible, and a detailed description of the first plane (P1) may also be substantially equally applied to other planes included in the memory cell array 110.

The first plane (P1) may include first to m-th pages (PG1 to PGm) (where ‘m’ is an integer of 2 or greater). Each of the first to m-th pages (PG1 to PGm) may be a set of memory cells that are accessed simultaneously in a read operation and output a voltage (or current) corresponding to stored data. That is, a page may be a unit of the read operation. In addition, memory cells included in each of the first to m-th pages (PG1 to PGm) may be connected to one word line corresponding to each of the first to m-th pages (PG1 to PGm).

The read operation for the first plane (P1) may include a cell read operation (or process) (CRP), a cache update operation (CUP), and a data output operation (DOP). In FIG. 4, a read operation for the second page (PG2) of the first plane (P1) is illustrated as an example.

The cell read operation (CRP) may include detecting data stored in a selected page among the first to m-th pages (PG1~PGm) and storing the detected data in the first page buffer (PB_P1). According to one embodiment, the cell read operation (CRP) may include an operation of precharging bit lines (BL) connected to the selected page, an operation of setting a voltage corresponding to data stored in memory cells included in the selected page to the bit lines (BL), and an operation of detecting and storing the voltage of the bit lines (BL).

To this end, the first page buffer (PB_P1) may include a precharge circuit for precharging the bit lines (BL), a sense amplifier for detecting the voltage of the bit lines (BL), and a latch circuit for storing data corresponding to the detected voltage.

The cache update operation (CUP) may include moving data stored in the first page buffer (PB_P1) to the first cache buffer (CB_P1) and storing the data. According to one embodiment, the cache update operation (CUP) may include accessing the latch circuit of the first page buffer (PB_P1), moving data stored in the latch circuit to the first cache buffer (CB_P1), and storing the data. To this end, the first cache buffer (CB_P1) may include a latch circuit for storing data received from the first page buffer (PB_P1).

The data output operation (DOP) may include outputting data stored in the first cache buffer (CB_P1) as data (DATA) through the I/O interface 170. According to one embodiment, the data output operation (DOP) may include accessing the latch circuit of the first cache buffer (CB_P1), moving data stored in the latch circuit to the I/O interface 170, and outputting the data.

According to one embodiment, the cell read operation (CRP) and the data output operation (DOP) may be performed in parallel at the same time (i.e., simultaneously). The above-described operation may be possible because the page of the first plane (P1) and the first page buffer (PB_P1), which are targets to be accessed in the cell read operation (CRP), are physically different from the first cache buffer (CB_P1) that is a target to be accessed in the data output operation (DOP). Due to such parallel execution, a time required for the read operation can be reduced.

According to one embodiment, the cell read operation (CRP) and the cache update operation (CUP) can be performed in parallel at the same time.

For example, a time section in which the first page buffer (PB_P1) is accessed in the cell read operation (CRP) and a time section in which the first page buffer (PB_P1) is accessed in the cache update operation (CUP) may be temporally separated from each other (or may not overlap each other). In the cache update operation (CUP), the first page buffer (PB_P1) may be continuously accessed, but in the cell read operation (CRP), the first page buffer (PB_P1) may not be accessed while an operation (hereinafter referred to as a precharge operation) of precharging bit lines (BL) connected to a selected page and an operation of setting a voltage corresponding to data stored in memory cells included in the selected page to the bit lines (BL) are performed. Therefore, the above-described temporal separation may be made possible by controlling the cache update operation (CUP) to overlap at least one of the precharge operation and the setting operation without overlapping the operation (hereinafter referred to as the sensing and storing operation) of sensing and storing the voltage of the bit lines (BLs).

In another example, a part of the first page buffer (PB_P1) accessed in the cell read operation (CRP) and another part of the first page buffer (PB_P1) accessed in the cache update operation (CUP) may be physically separated from each other. That is, the latch circuit of the first page buffer (PB_P1) may include a plurality of latches (e.g., a first latch and a second latch), and data of a memory cell may be stored in each of the first latch and the second latch, but the first latch may be accessed in the cell read operation (CRP) and the second latch may be accessed in the cache update operation (CUP).

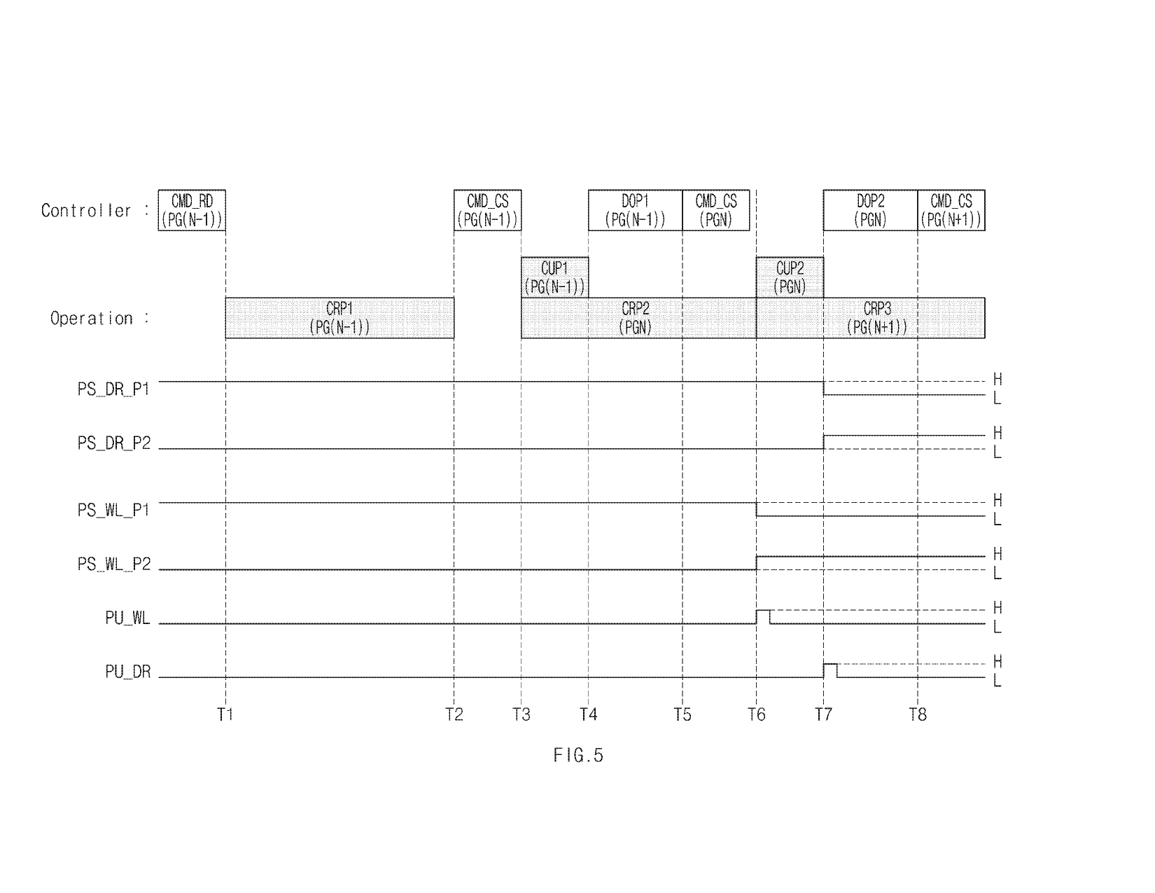

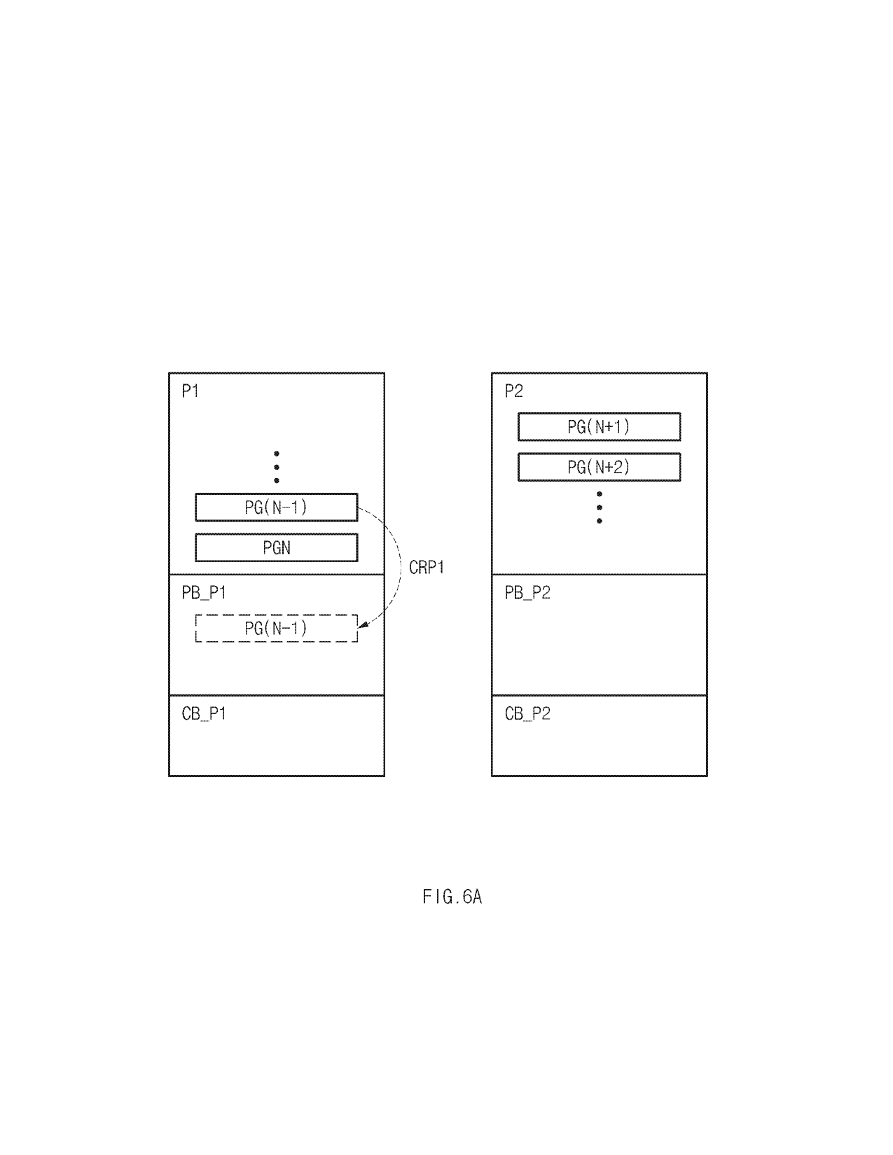

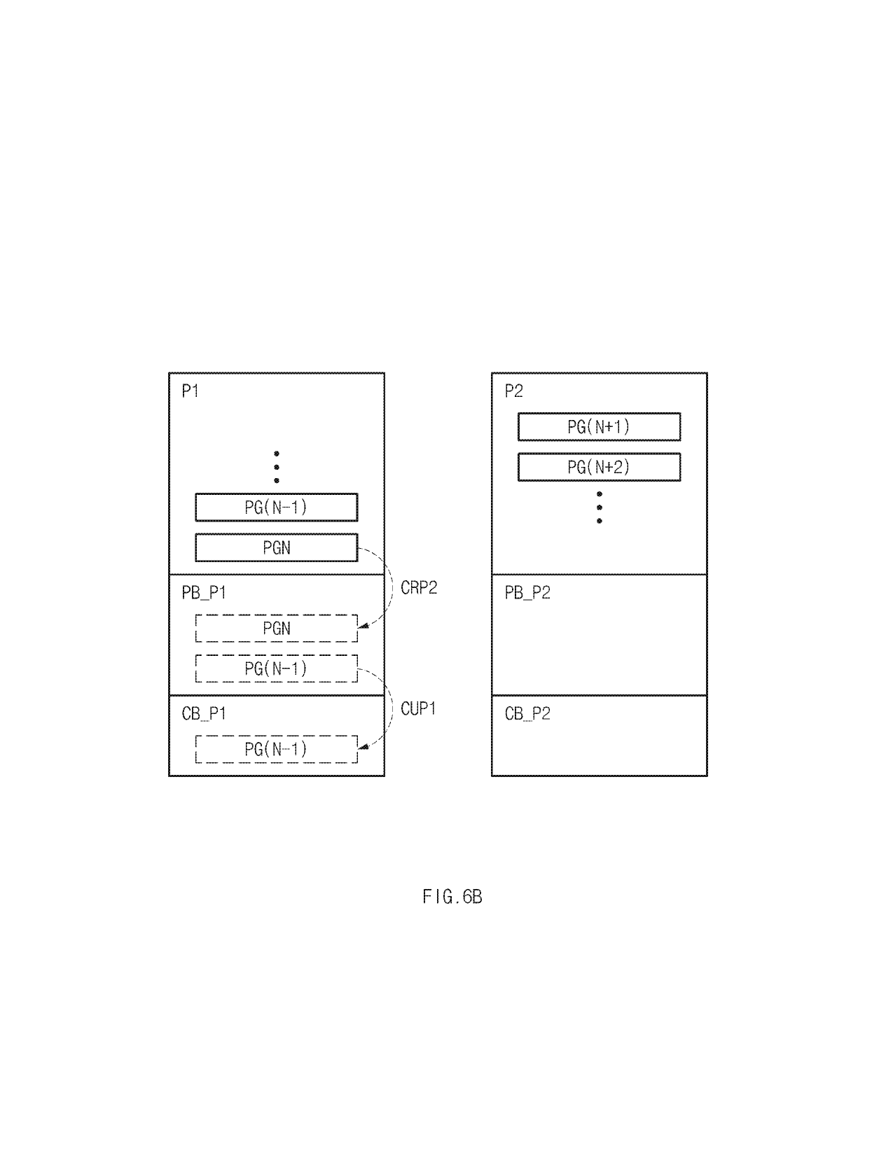

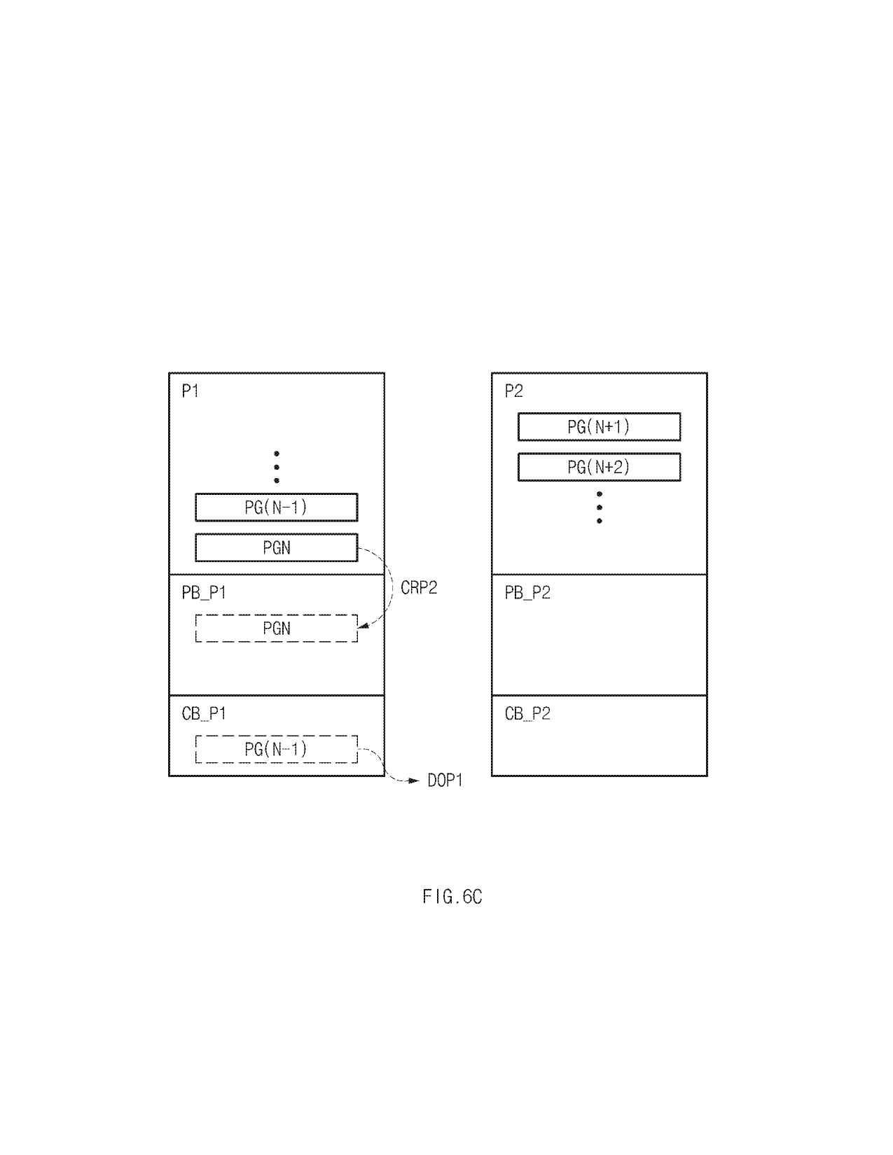

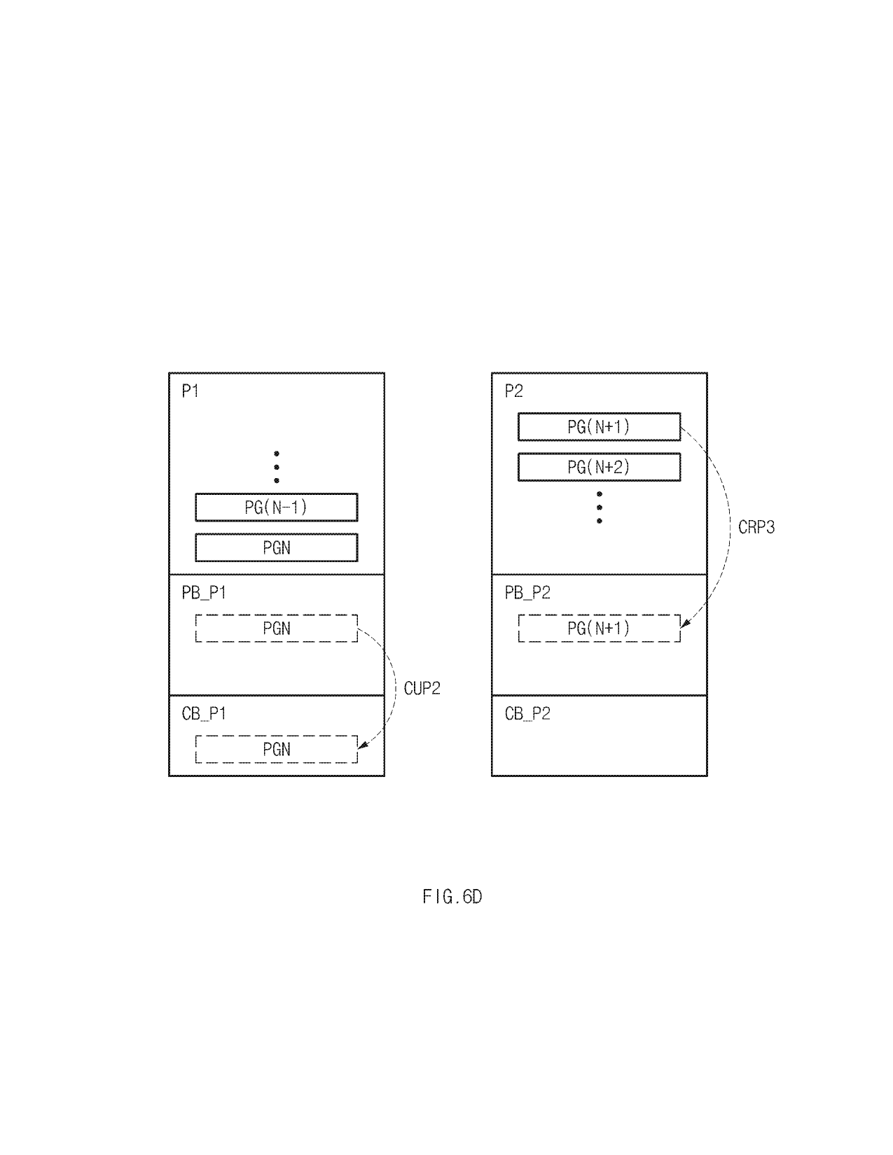

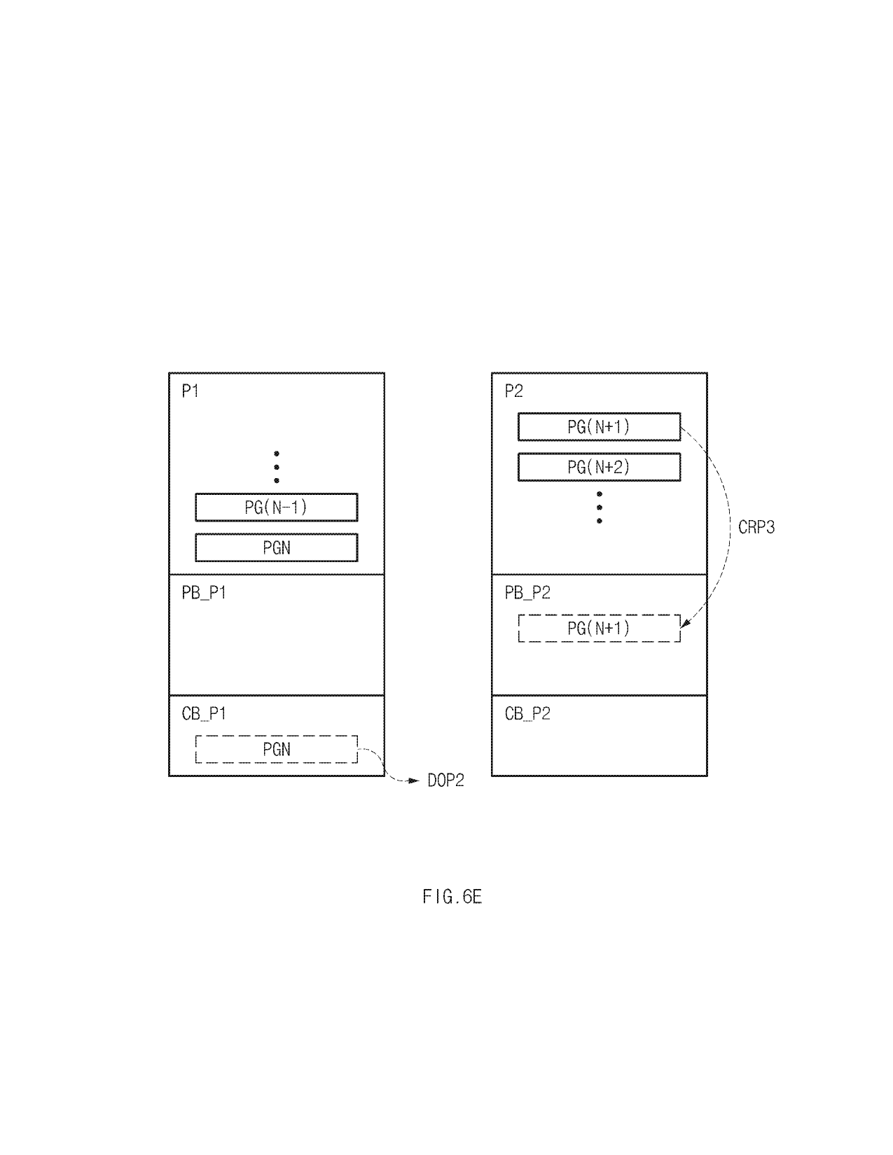

FIG. 5 is a timing diagram illustrating example operations of the memory system shown in FIG. 1 according to embodiments of the present disclosure. FIGS. 6A to 6E are schematic diagrams briefly illustrating example operations of the memory system in each time section shown in FIG. 5 according to embodiments of the present disclosure.

Referring to FIGS. 5 and 6A to 6E, timing diagrams for performing the read operation for the (N-1)-th to the (N+1)-th pages (PG(N-1) to PG(N+1)) (where ‘N’ is an integer of 2 or greater) are illustrated. It is assumed that the read operations for the (N-1)-th to (N+1)-th pages (PG(N-1) to PG(N+1)) are sequentially performed from the (N-1)-th page (PG(N-1)) to the (N+1)-th page (PG(N+1)). In addition, it is assumed that the (N-1)-th page (PG(N-1)) and the N-th page (PGN) are included in the first plane (P1), and the (N+1)-th page (PG(N+1)) is included in the second plane (P2).

Before the first time point (T1), the memory controller 50 may transmit a read command (CMD_RD) for the (N-1)-th page (PG(N-1)) to the memory device 100. The read command (CMD_RD) may control initiation of the read operation of the memory device 100, and may request the cell read operation for the (N-1)-th page (PG(N-1)).

Also, it is assumed that, before the first time point (T1), the first word-line plane selection signal (PS_WL_P1) and the first data register plane selection signal (PS_DR_P1) have a logic high level (H), and the second word-line plane selection signal (PS_WL_P2) and the second data register plane selection signal (PS_DR_P2) have a logic low level (L). In the present disclosure, the logic high level (H) may be a voltage level for activating a target to be controlled, and the logic low level (L) may be a voltage level for deactivating the target to be controlled.

At the first time point (T1), the memory device 100 having received the read command (CMD_RD) for the (N-1)-th page (PG(N-1)) may perform a cell read operation (CRP1) for the (N-1)-th page (PG(N-1)).

As shown in FIG. 6A, when the cell read operation (CRP1) is performed, data stored in the (N-1)-th page (PG(N-1)) may be detected and stored in the first page buffer (PB_P1).

At the second time point (T2), the memory controller 50 may transmit a cache sensing command (CMD_CS) for the (N-1)-th page (PG(N-1)) to the memory device 100. The cache sensing command (CMD_CS) for the (N-1)-th page (PG(N-1)) may request data output from the memory device 100, and may request a cache update operation and a data output operation for the (N-1)-th page (PG(N-1)), and a cell read operation for the N-th page (PGN) which is the next page after the (N-1)-th page (PG(N-1)).

At the third time point (T3), the memory device 100 having received the cache sensing command (CMD_CS) for the (N-1)-th page (PG(N-1)) may perform a cache update operation (CUP1) for the (N-1)-th page (PG(N-1)) and a cell read operation (CRP2) for the N-th page (PGN).

As shown in FIG. 6B, when the cache update operation (CUP1) is performed, data of the (N-1)-th page (PG(N-1)) stored in the first page buffer (PB_P1) may be transferred to the first cache buffer (CB_P1) and stored in the first cache buffer (CB_P1).

In addition, when the cell read operation (CRP2) is performed, data stored in the N-th page (PGN) may be detected and stored in the first page buffer (PB_P1).

At the fourth time point (T4), when the cache update operation (CUP1) for the (N-1)-th page (PG(N-1)) is completed, the memory device 100 may perform a data output operation (DOP1) for the (N-1)-th page (PG(N-1)).

As shown in FIG. 6C, when the data output operation (DOP1) is performed, data of the (N-1)-th page (PG(N-1)) stored in the first cache buffer (CB_P1) may be output as data (DATA) through the I/O interface 170.

In addition, the data output operation (DOP1) and the cell read operation (CRP2) may be performed in an overlapping manner.

At the fifth time point (T5), the memory controller 50 may transmit a cache sensing command (CMD_CS) for the N-th page (PGN) to the memory device 100. The cache sensing command (CMD_CS) for the N-th page (PGN) may request not only a cache update operation and a data output operation for the N-th page (PGN), but also a cell read operation for the (N+1)-th page (PG(N+1)) that is the next page after the N-th page (PGN).

At the sixth time point (T6), the memory device 100 having received the cache sensing command (CMD_CS) for the N-th page (PGN) may perform a cache update operation (CUP2) for the N-th page (PGN) and a cell read operation (CRP3) for the (N+1)-th page (PG(N+1)).

As shown in FIG. 6D, when the cache update operation (CUP2) is performed, data of the N-th page (PGN) stored in the first page buffer (PB_P1) may be transferred to the first cache buffer (CB_P1) and stored therein.

Since the N-th page (PGN) is included in the first plane (P1) and the (N+1)-th page (PG(N+1)) is included in the second plane (P2), a word line corresponding to the second plane (P2) may be activated in order to perform the cell read operation (CRP3) for the (N+1)-th page (PG(N+1)). However, if the plane selected is changed before the cell read operation (CRP2) for the N-th page (PGN) is completed, the cell read operation (CRP2) may not be performed normally, so that the plane change may be performed after the cell read operation (CRP2) is completed.

Accordingly, the first plane update signal (PU_WL) may be activated at the sixth time point (T6) when the cell read operation (CRP2) is completed. That is, at the sixth time point (T6), the first plane update signal (PU_WL) may transition from a logic low level (L) to a logic high level (H), and then transition back to a logic low level (L) after a predetermined time has elapsed. In response to an edge (e.g., a rising edge) of the first plane update signal (PU_WL), the first word-line plane selection signal (PS_WL_P1) may transition from a logic high level (H) to a logic low level (L), and the second word-line plane selection signal (PS_WL_P2) may transition from a logic low level (L) to a logic high level (H). As the second word-line plane selection signal (PS_WL_P2) having a logic high level (H) is transmitted to the address control circuit 132, the address control circuit 132 may generate a row address (X-ADDR) capable of activating a word line corresponding to the second plane (P2) and transmit the row address (X-ADDR) to the first decoder 150. Accordingly, a cell read operation (CRP3) for the (N+1)-th page (PG(N+1)) is performed, so that data stored in the (N+1)-th page (PG(N+1)) can be detected and stored in the second page buffer (PB_P2).

At the seventh time point (T7), when the cache update operation (CUP2) for the N-th page (PGN) is completed, the memory device 100 may perform a data output operation (DOP2) for the N-th page (PGN).

As shown in FIG. 6E, when the data output operation (DOP2) is performed, the data of the N-th page (PGN) stored in the first cache buffer (CB_P1) may be output as data (DATA) through the I/O interface 170.

Since the data output operation (DOP2) is an operation in which the I/O interface 170 outputs data of the N-th page (PGN) stored in the first cache buffer (CB_P1), the data register corresponding to the first plane (P1) may no longer need to be activated.

Accordingly, the second plane update signal (PU_DR) may be activated at the seventh time point (T7) at which the cache update operation (CUP2) is completed. That is, at the seventh time point (T7), the second plane update signal (PU_DR) may transition from a logic low level (L) to a logic high level (H), and then transition back to a logic low level (L) after a predetermined time has elapsed. In response to an edge (e.g., a rising edge) of the second plane update signal (PU_DR), the first data register plane selection signal (PS_DR_P1) may transition from a logic high level (H) to a logic low level (L), and the second data register plane selection signal (PS_DR_P2) may transition from a logic low level (L) to a logic high level (H). As the second data register plane selection signal (PS_DR_P2) having a logic high level (H) is transmitted to the address control circuit 132, the address control circuit 132 may generate a column address (Y-ADDR) that can activate a data register corresponding to the second plane (P2) and transmit the column address to the second decoder 160. Accordingly, the data registers (PB_P2, CB_P2) corresponding to the second plane (P2) are activated to prepare a cache update operation for the (N+1)-th page (PG(N+1)).

As illustrated in FIG. 5, the first plane update signal (PU_WL) may be activated earlier than the second plane update signal (PU_DR).

At the eighth time point (T8), the memory controller 50 may transmit a cache sensing command (CMD_CS) for the (N+1)-th page (PG(N+1)) to the memory device 100. The cache sensing command (CMD_CS) for the (N+1)-th page (PG(N+1)) may request not only a cache update operation and a data output operation for the (N+1)-th page (PG(N+1)), but also a cell read operation for the (N+2)-th page (PG(N+2)) that is the next page after the (N+1)-th page (PG(N+1)). Although not shown in FIG. 5, read operations for subsequent pages may be sequentially performed after the eighth time point (T8).

As shown in FIG. 5, according to the present disclosure, the cache update operation (CUP1) for the (N-1)-th page (PG(N-1)) and the cell read operation (CRP2) for the N-th page (PGN) may be performed in an overlapping manner, so that a time required for the read operation can be reduced. In particular, a time required from the completion of the data output operation (DOP1) for the (N-1)-th page (PG(N-1)) to the initiation of the data output operation (DOP2) for the N-th page (PGN) may be significantly reduced.

In addition, even in instances in which the plane that is a target of the cache update operation and the plane that is a target of the cell read operation are different from each other, the cache update operation (CUP2) for the N-th page (PGN) and the cell read operation (CRP3) for the (N+1)-th page (PG(N+1)) may be performed in an overlapping manner, thereby reducing the time required for the read operation.

In FIG. 5, a start time of the cache update operation for a specific page (e.g., the (N-1)-th page PG(N-1)) and a start time of the cell read operation for the subsequent page (e.g., the N-th page PGN) coincide with each other so that the two start times are shown to overlap each other, but the scope of the present disclosure is not limited thereto. According to another embodiment, a start time of the cache update operation for a specific page (e.g., the (N-1)-th page PG(N-1)) may be set to be later than a start time of the cell read operation for the subsequent page (e.g., the N-th page PGN), so that the two start times may also overlap each other.

According to another embodiment, a start time of the cache update operation for a specific page (e.g., the (N-1)-th page PG(N-1)) may be set to be earlier than a start time of the cell read operation for the subsequent page (e.g., the N-th page PGN), so that the two start times may also partially overlap each other.

That is, according to the present disclosure, at least a part of the cache update operation for a specific page (e.g., the (N-1)-th page (PG(N-1))) may overlap the cell read operation for the subsequent page (e.g., the N-th page (PGN)).

As is apparent from the above description, according to the embodiments of the present disclosure, a cache update operation for a specific page of a semiconductor memory device and a cell read operation for a subsequent page are performed in an overlapping manner, thereby reducing a time required for the read operation.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A memory device comprising:
a memory cell array including a first page and a second page, each of which includes a plurality of memory cells;
a page buffer configured to detect data stored in a selected page among the first page and the second page and store the detected data therein;
a cache buffer configured to receive data stored in the page buffer and store the received data; and
a control circuit configured to perform a cache update operation for the first page and a cell read operation for the second page,
wherein at least a part of the cache update operation for the first page overlaps the cell read operation for the second page.

2. The memory device according to claim 1, wherein, in the cache update operation for the first page, the cache buffer is further configured to receive data of the first page from the page buffer, and store the received data of the first page.

3. The memory device according to claim 1, wherein,
in the cell read operation for the second page, the page buffer is further configured to detect data stored in the second page, and store the detected data of the second page.

4. The memory device according to claim 1, wherein the control circuit is further configured to:
overlap the cell read operation for the second page with a data output operation in which data of the first page stored in the cache buffer is output through an input and output (I/O) interface.

5. The memory device according to claim 1, wherein, when performing the cache update operation for the first page, the control circuit is further configured to:
overlap at least one of a precharge operation and a setting operation that are included in the cell read operation of the second page, wherein
the precharge operation is used to precharge bit lines connected to the second page; and
the setting operation is used to set a voltage corresponding to data stored in memory cells included in the second page to the bit lines.

6. The memory device according to claim 1, wherein:
the page buffer includes a first latch and a second latch,
wherein
the first latch is accessed in the cell read operation for the second page; and
the second latch is accessed in the cache update operation for the first page.

7. The memory device according to claim 1, wherein:
the first page and the second page are included in the same plane.

8. The memory device according to claim 7, wherein:
a page buffer configured to output data of the first page in the cache update operation for the first page is equal to a page buffer configured to store data stored in the second page in the cell read operation for the second page.

9. The memory device according to claim 1, wherein:
the first page and the second page are included in different planes.

10. The memory device according to claim 9, wherein:
a page buffer configured to output data of the first page in the cache update operation for the first page is equal to a page buffer configured to store data stored in the second page in the cell read operation for the second page.

11. The memory device according to claim 9, wherein the control circuit includes:
a plane selection circuit configured to independently select a word line corresponding to a selected plane among a plurality of planes included in the memory cell array and a data register corresponding to the selected plane among the plurality of planes,
wherein the data register includes the page buffer and the cache buffer.

12. The memory device according to claim 11, wherein the plane selection circuit includes:
a first plane selector configured to generate a plurality of word-line plane selection signals corresponding to the plurality of planes,
wherein a word-line plane selection signal corresponding to the selected plane among the plurality of word-line plane selection signals has a logic high level.

13. The memory device according to claim 12, wherein the first plane selector includes:
a plurality of D flip-flops configured to generate the plurality of word-line plane selection signals in response to a first plane update signal.

14. The memory device according to claim 13, wherein:
the first plane update signal is activated after the cell read operation for the first page is completed.

15. The memory device according to claim 11, wherein the plane selection circuit includes:
a second plane selector configured to generate a plurality of data register plane selection signals corresponding to the plurality of planes,
wherein a data register plane selection signal corresponding to the selected plane among the plurality of data register plane selection signals has a logic high level.

16. The memory device according to claim 15, wherein the second plane selector includes:
a plurality of D flip-flops configured to generate the plurality of data register plane selection signals in response to a second plane update signal.

17. The memory device according to claim 14, wherein the control circuit is further configured to:
activate the second plane update signal after the cache update operation for the first page is completed.

18. The memory device according to claim 9, wherein:
a first plane update signal for selecting a word line corresponding to a selected plane among the plurality of planes is activated earlier than a second plane update signal for selecting a data register corresponding to the selected plane among the plurality of planes.

19. A memory device comprising:
a memory cell array including a first page and a second page, each of which includes a plurality of memory cells;
a page buffer configured to detect data stored in a selected page among the first page and the second page and store the detected data therein;
a cache buffer configured to receive data stored in the page buffer and store the received data; and
a control circuit configured to perform an operation of precharging at least one bit line connected to the second page when the cache buffer receives data of the first page stored in the page buffer.

20. A method for operating a memory device comprising:
detecting data stored in a first page of a memory cell array and storing the detected data in a page buffer;
moving data of the first page stored in the page buffer to a cache buffer and storing the data in the cache buffer; and
detecting data stored in a second page of the memory cell array and storing the detected data in the page buffer,
wherein
the moving data of the first page to the cache buffer and storing the data in the cache buffer and the detecting data of the second page and storing the detected data in the page buffer are performed in an overlapping manner.
